(19) United States
(12) Patent Application Publication
(10) Pub. No.: US 2018/0217646 A1
(43) Pub. Date: Aug. 2, 2018

(54) LIQUID COOLING SYSTEMS FOR HEAT GENERATING ELECTRONIC DEVICES THAT REPORT COOLANT TEMPERATURE VIA A TACHOMETER SIGNAL

(71) Applicant: Asetek Danmark A/S, Aalborg East (DK)

(72) Inventors: Bjarne W. Mikkelsen, Vodskov (DK); Steven B. Branton, Ventura, CA (US); Freddy Jensen, Vestbjerg (DK); Kasper Fuglsang, Gistrup (DK)

(21) Appl. No.: 15/883,170

(22) Filed: Jan. 30, 2018

Related U.S. Application Data
(60) Provisional application No. 62/451,978, filed on Jan. 30, 2017.

(51) Int. Cl. G06F 1/20; H01L 23/473

(52) U.S. Cl. CPC G06F 1/206; H01L 23/473

(57) ABSTRACT

A liquid cooling system for a computer. The liquid cooling system may have a cold plate configured to be positioned on a heat generating electronic device of the computer, the cold plate configured to pass a coolant therethrough. The liquid cooling system may also include a temperature sensor configured to generate a coolant temperature signal indicative of a temperature of the coolant. The liquid cooling system may also include a pump in fluid communication with the cold plate, the pump configured to circulate the coolant through the cold plate and send a pump signal to a control system associated with the computer. The pump signal may represent a tachometer signal for the pump and the coolant temperature signal of the coolant.

### RELATED APPLICATIONS

This application claims the benefit of U.S. Provisional Application No. 62/451,978, filed Jan. 30, 2017, which is incorporated by reference in its entirety.

### TECHNICAL FIELD

The present disclosure relates generally to liquid cooling systems for heat generating electronic devices, and more particularly, liquid cooling systems that report coolant temperature and/or temperature conditions via a tachometer signal.

### BACKGROUND

Coolant temperature can be an important operating parameter of liquid cooling systems for computer systems or other systems having heat generating electronic devices. If the coolant becomes too hot it will first reduce the useful life of the liquid cooling system, second damage the liquid cooler preventing it from cooling, and third cause damage which results in coolant loss that may damage the host computer. These consequences can occur sequentially as the coolant temperature increases above the safe operating temperature range. Coolant temperature is not an operating parameter that is currently monitored by most computers and therefore current computer systems are not compatible (e.g., physical electrical connections do not exist) with a liquid cooling system that measures and outputs coolant temperature. The disclosed systems and methods are directed to overcoming one or more of the problems set forth above.

### SUMMARY

In accordance with the present disclosure, one aspect of the present disclosure is directed to a liquid cooling system for a heat generating electronic device. The liquid cooling system may include a cold plate configured to be positioned on the heat generating electronic device, the cold plate configured to pass a coolant therethrough. The liquid cooling system may also include a temperature sensor configured to generate a coolant temperature signal indicative of a temperature of the coolant. The liquid cooling system may also include a pump in fluid communication with the cold plate, the pump configured to circulate the coolant through the cold plate and send a pump signal to a control system associated with the heat generating electronic device. The pump signal may represent a tachometer signal for the pump and the coolant temperature signal of the coolant.

Another aspect of the present disclosure is directed to a method of controlling a liquid cooling system for a heating generating electronic device. The method may include circulating a coolant through a cold plate configured to be positioned on the heat generating electronic device. The method may also include measuring a temperature of the coolant via a temperature sensor configured to generate a coolant temperature signal indicative of the temperature of the coolant. The method may further include pumping the coolant through the cold plate via a pump configured to send a pump signal to a control system associated with the heating generating electronic device. The pump signal may represent a tachometer signal for the pump and the coolant temperature signal of the coolant.

Another aspect of the present disclosure is directed to a liquid cooling system for a heat generating electronic device. The system may include a cold plate configured to be positioned on the heat generating electronic device, the cold plate configured to pass a coolant therethrough. The system may also include a temperature sensor configured to generate a coolant temperature signal indicative of a temperature of the coolant. The system may further include a pump in fluid communication with the cold plate, the pump configured to circulate the coolant through the cold plate and send a pump signal to a control system associated with the heat generating electronic device. The pump signal may represent a tachometer signal for the pump and when the coolant temperature goes out-of-bounds the pump signal is held at a specific state indicating and out-of-bounds temperature to the control system.

Another aspect of the present disclosure is directed to a method of controlling a liquid cooling system for a heat generating electronic device. The method may include circulating a coolant through a cold plate configured to be positioned on the heat generating electronic device. The method may also include measuring a temperature of the coolant via a temperature sensor configured to generate a coolant temperature signal indicative of the temperature of the coolant. The method may further include pumping the coolant through the cold plate via a pump configured to send a pump signal to a control system associated with the heat generating electronic device. The pump signal may represent a tachometer signal for the pump and when the coolant temperature goes out-of-bounds the pump signal is held at a specific state indicating and out-of-bounds temperature to the control system.

Another aspect of the present disclosure is directed to a liquid cooling system for a heat generating electronic device. The system may include a pump configured to circulate a coolant through the system and send a pump signal to a control system associated with heat generating electronic device, wherein circulating the coolant removes heat from the heat generating electronic device. The system may also include a temperature sensor configured to generate a coolant temperature signal indicative of a temperature of the coolant. The pump signal may represent a tachometer signal for the pump and the coolant temperature signal of the coolant.

Another aspect of the present disclosure is directed to a liquid cooling system for a heat generating electronic device. The system may include a pump configured to circulate a coolant through the system and send a pump signal to a control system associated with heat generating electronic device, wherein circulating the coolant removes heat from the heat generating electronic device. The system may also include a temperature sensor configured to generate a coolant temperature signal indicative of a temperature of the coolant. The pump signal represents a tachometer signal for the pump and when the coolant temperature goes out-of-bounds the pump signal is held at a specific state indicating an out-of-bounds temperature to the control system.

Another aspect of the present disclosure is directed to a liquid cooling system for a heat generating electronic device. The system may include a cold plate configured to be positioned on the heat generating electronic device, the cold plate configured to pass a coolant therethrough. The system may also include a temperature sensor configured to generate a coolant temperature signal indicative of a temperature of the coolant. The system may further include a flow sensor operatively connected to the temperature sensor and in fluid communication with the cold plate, the flow sensor is configured to receive the coolant temperature signal and send a device signal to a control system associated with the heat generating electronic device. The device signal may indicate to the control system when the coolant temperature goes out-of-bounds by holding the device signal at a specific state indicative of out-of-bounds temperature.

Another aspect of the present disclosure may be directed to a liquid cooling system for a heat generating electronic device. The system may include a cold plate configured to be positioned on the heat generating electronic device, the cold plate configured to pass a coolant therethrough. The system may also include a temperature sensor configured to generate a coolant temperature signal indicative of a temperature of the coolant. The system may further include a pump in fluid communication with the cold plate, the pump configured to circulate the coolant through the cold plate and send a pump signal to a control system associated with the heat generating electronic device. The pump may be programmed to substitute the pump signal so it represents the coolant temperature signal of the coolant rather than the tachometer signal for the pump.

Another aspect of the present disclosure may be directed to a liquid cooling system for a heat generating electronic device. The system may include a cold plate configured to be positioned on the heat generating electronic device, the cold plate configured to pass a coolant therethrough. The system may also include a temperature sensor configured to generate a coolant temperature signal indicative of a temperature of the coolant. The system may further include a device operatively coupled to the temperature sensor and configured to send a device signal representative of a running pump to a control system associated with the heat generating electronic device. The device is programmed to send the device signal, whether or not the device signal is representative of an actual pump, while the coolant temperature is in-bounds and when the coolant temperature goes out-of-bounds the device signal is held at a specific state indicating an out-of-bounds temperature to the control system associated with the heat generating device.

### BRIEF DESCRIPTION OF THE FIGURES

FIG. 1 is a schematic of a liquid cooling system, according to an exemplary embodiment.

FIG. 2 is a schematic of a liquid cooling system, according to an exemplary embodiment.

FIG. 3 is a schematic of a pump/cold plate assembly, according to an exemplary embodiment.

FIG. 4 is a plot of four pump signals vs. time.

FIG. 5 is a schematic of a liquid cooling system, according to an exemplary embodiment.

### DETAILED DESCRIPTION

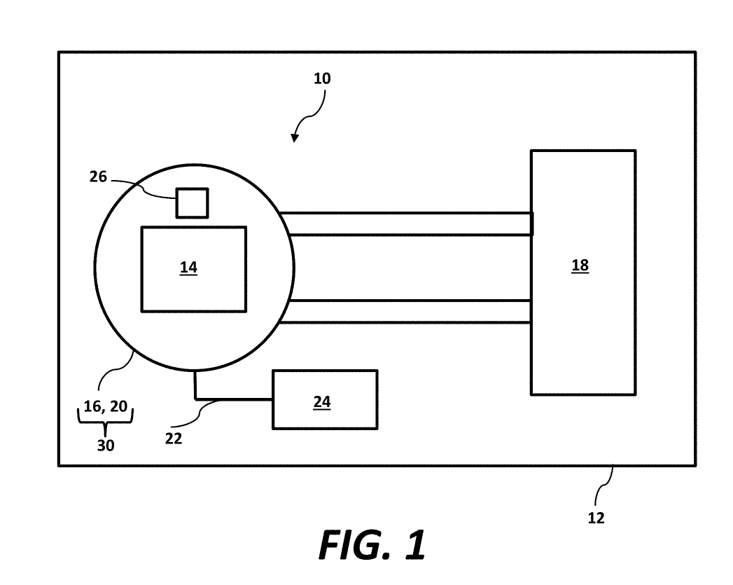

FIG. 1 is a schematic for a liquid cooling system 10, according to an exemplary embodiment. System 10 may be configured to cool a computer 12, server, or other electronic device, which may have heat generating electronic component(s) 14, for example, CPU, GPU, etc. System 10 may include a cold plate 16 that may be configured to be positioned on the heat generating component 14. Cold plate 16 may be fluidly coupled to a cooling device 18 and configured to circulate a coolant therethrough in order to remove heat from heat generating electronic component 14. Cooling device 18 may be for example, a liquid-to-air heat exchanger or liquid-to-liquid heat exchanger. In some embodiments, cooling device 18 may be a liquid-to-liquid heat exchanger configured to transfer heat from the coolant circulating in system 10 to another coolant circulating in a liquid cooling system external to computer or server 12. System 10 may also include a pump 20 fluidly coupled to cold plate 16 configured to circulate the coolant through cold plate 16 and cooling device 18. System 10 may include conduits configured to circulate coolant between cold plate 16/pump 20 and cooling device 18. Pump 20 may be configured to send a pump signal 22 to a control system 24, which may be associated with computer 12 and/or heat generating electronic component 14.

In some embodiments, as shown in FIG. 1, pump 20 and cold plate 16 may be integrated into a pump/cold plate assembly 30 that is configured to be positioned on the heat generating component. In other embodiments, pump 20 and cold plate 16 may be separate components fluidly connected, for example, using conduits. System 10 may also include a temperature sensor 26 configured to generate a coolant temperature signal indicative of a temperature of the coolant. In some embodiments, as shown in FIG. 1, temperature sensor 26 may be integrated as part of assembly 30. For example, assembly 30 may include a printed circuit board assembly (PCBA) and temperature sensor 26 may be mounted to the PCBA. In some embodiments, temperature sensor 26 may be mounted in a coolant well at, for example, the outlet of pump 20 so it may measure the coolant temperature of coolant as it is discharged from pump 20. In other embodiments, temperature sensor 26 may be positioned elsewhere along the flow path of the coolant.

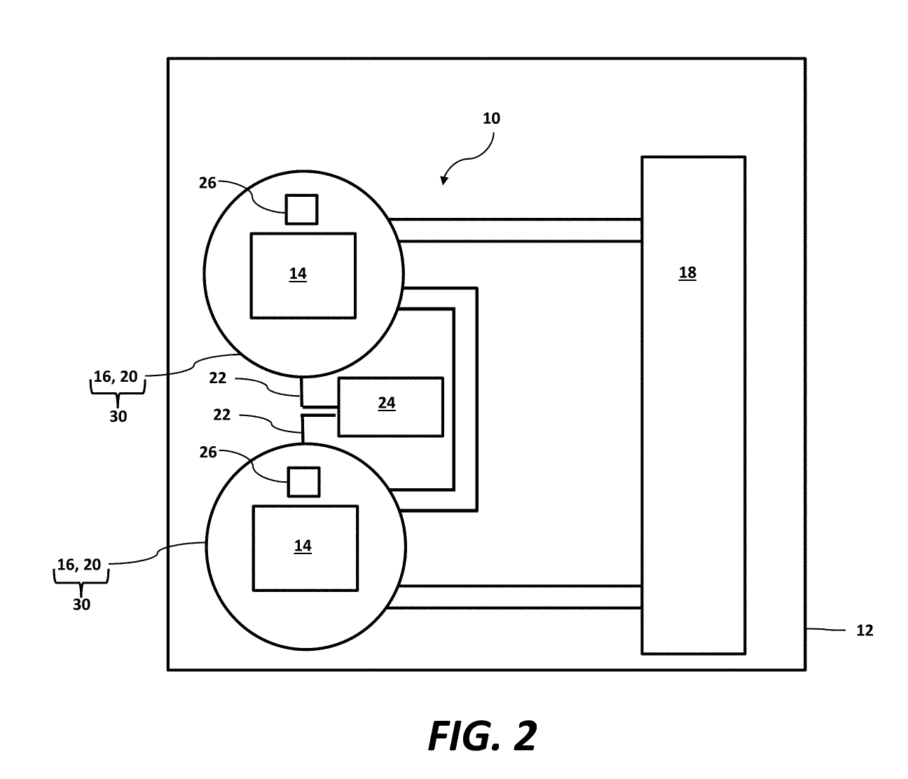

In some embodiments, liquid cooling system 10 may be configured to circulate coolant through a plurality of cold plates 16 in order to cool a plurality of heat generating electronic components 14 of computer 12. For example, FIG. 2 is a schematic of liquid cooling system 10 having a plurality of pump/cold plate assemblies 30, where each pump/cold plate assembly 30 is positioned on a different heat generating electronic component 14.

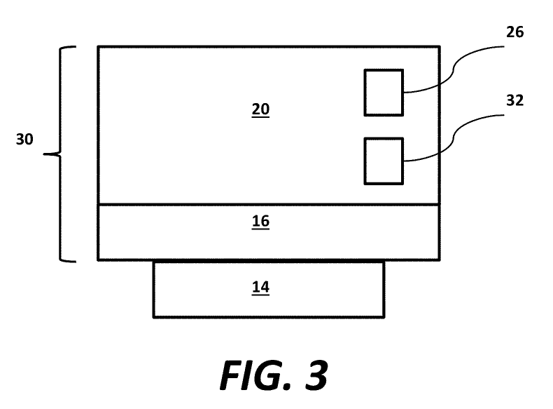

FIG. 3 is a schematic of a pump/cold plate assembly 30 of FIG. 1. As shown in FIG. 3, cold plate 16 may be positioned on heat generating component 14 and cold plate 16 and 20 may be integrated into assembly 30. For some embodiments, based on the positioning of temperature sensor 26 there may be an offset for the measured coolant temperature from the actual coolant temperature based on the difference between the liquid temperature and the ambient air temperature surrounding pump 20. For these embodiments, assembly 30 may also include an ambient temperature sensor 32 configured to measure the ambient temperature around assembly 30 enabling the offset for the measured coolant temperature to be determined and applied to obtain the actual coolant temperature. Ambient temperature sensor 34 may be mounted to the PCBA of assembly 30. According to some embodiments, coolant temperature sensor 32 may be positioned such that it is sufficiently surrounded by the coolant and therefore unaffected by the ambient temperature, preventing the need for an ambient temperature sensor 34 and an offset determination.

As explained above, coolant temperature is not an operating parameter that is currently monitored by most computers and therefore current computer systems are not compatible with a liquid cooling system that measures and outputs coolant temperature because physical electrical connections do not exist to receive the coolant temperature signal. The disclosed liquid cooling systems 10, 100 solves this problem by programming pump signal 22 to include information about pump 20 as well as the coolant temperature.

Most current computers have a tachometer (tach) signal port available that is intended to be used to monitor the speed of a pump or fan and also detect irregular operation of the pump or fan. System 10 as described herein, may be configured to utilize the existing tach signal port of control system 24 of computer 12 to send pump signal 22, which may provide information about pump 20 as well as the coolant temperature. For example, pump signal 22 may include a tachometer signal portion and a temperature signal portion. In some embodiments, pump 20 may be programmed so pump signal 22 just represents the coolant temperature signal of the coolant rather than the tachometer signal for the pump.

The tachometer signal portion of pump signal 22 may be used to monitor the speed of pump 20 and also detect irregular operation of pump 20. Such detection may be simple or more complex. For example, detection of irregular operation may include monitoring for a tach signal indicating zero speed, it may detect irregular operation by monitoring whether pump 20 is within normal operating speed bands, or it may monitor how quickly pump 20 responds to changes in power or duty cycle signals to predict when pump 20 may be at risk of failing.

In some embodiments, the temperature signal portion of pump signal 22 may be configured to signal control system 24 when the coolant temperature reaches one or more out-of-bounds conditions (e.g., greater than about 70° C.). In other words, the temperature signal portion of pump signal may simply indicate a high temperature state. In some embodiments, the temperature signal portion of pump signal 22 may signal when the temperature is out-of-bounds (e.g., too high) and control system 24 of computer 12 must take corrective action (e.g., forcing pump 20 to run at full speed). In some embodiments, rather than a simple binary state (e.g., high/not high) the temperature signal portion of pump signal 22 may transmit the coolant temperature to control system 24 enabling control system 24 to be programmed to determine when to take action. In some embodiments, system 10 may be configured to identify when coolant temperature is out-of-bounds and determine a corrective action based on how far the coolant temperature is out-of-bounds.

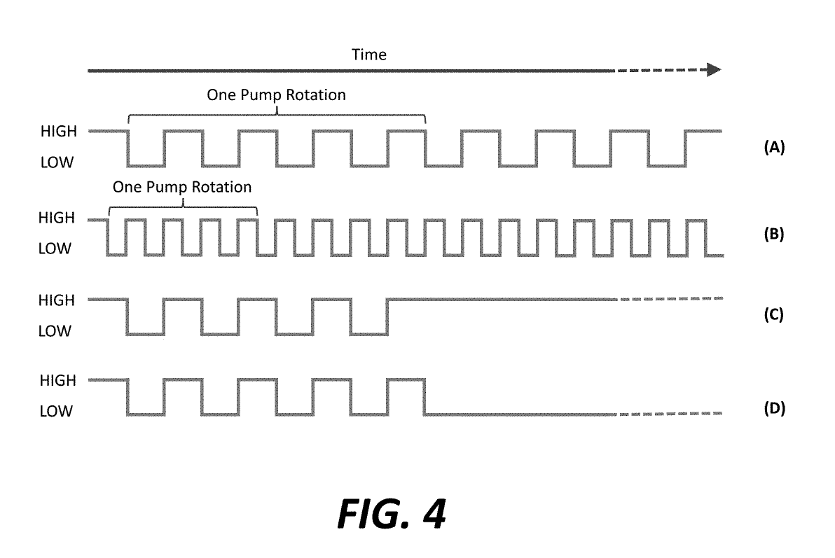

Pump signals traditionally report pump speed via a tach signal that is a square wave signal that shifts from high to low as the pump revolves. The number of shifts per revolution is dependent on the number of motor poles and is typically either 2, 4, or 8 shifts per revolution. For example, FIG. 4 shows a pump signal plot (A) where the pulse per second may be multiplied by a scalar to determine pump speed in revolutions per minute. Pump signal plot (B) represents a tach signal where the pump is running at twice the speed of the pump in plot (A).

In some embodiments, pump 20 may include hardware and software logic programmed to receive the coolant temperature signal from temperature sensor 26 and determine whether the coolant temperature is out-of-bounds (e.g., too high) and when an excessive temperature is detected locking pump signal 22 of pump 20 in a specified state (e.g., high or low state). A non-spinning pump 20 may also lock pump signal 22 in either its high or low state. Upon receiving the locked state pump signal 22, control system 24 may respond by taking one or more actions to address the situation. For example, in some embodiments control system 24 may respond as it would to a failed pump motor. For some embodiments, pump signal 22 may be locked low for an out-of-bounds temperature and locked high for a pump failure (e.g., non-spinning pump) enabling control system 24 to identify and differentiate between an out-of-bounds temperature vs. a pump failure enabling control system 24 to take appropriate action specific to the identified condition.

Pump signal 22 may be configured to represent a tachometer signal for pump 20 and the coolant temperature signal of the coolant measured by temperature sensor 26 by time slicing temperature measurements with pump speed measurements into pump signal 22. According to some embodiments, pump signal 22 may report speed and coolant temperature by alternating between the two signals on a fixed time basis. For example, speed may be reported normally via a set number of pulses per revolution (e.g., 2, 4, or 8 pulses per revolution) for a fixed window of time—the speed-reporting window. This report may range from 45 to 600 pulses per second during the speed-reporting window. During a second fixed window of time, coolant temperature may be reported in degrees Celsius plus 1000 resulting in 1000 to 1150 pulses per second. For some embodiments these two fixed windows may be equal spans of time and in other embodiments they may be different spans of time. For some embodiments, the windows may be separated by either a short period of time where the signal is locked high or low.

According to some embodiments, pump signal 22 may report the tach signal pump speed in RPM and coolant temperature in Celsius using a serial communication protocol and communicating these values one following the other via binary encoding. For example, a two-byte value may be used to communicate RPM and a one-byte value may be used to communicate coolant temperature.

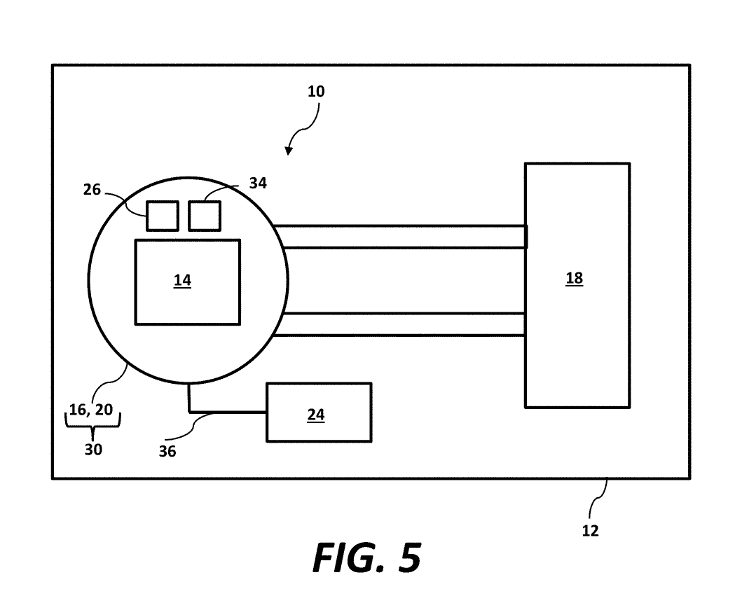

According to some embodiments, pump signal 22 may report the tach signal pump speed normally via a set number of pulses per rotation, as long as the coolant temperature is within a safe range. If the pump is stopped, the signal will be constantly high. For example, plot (C) of FIG. 5 shows a scenario where pump 20 is operating normally and pump signal is reporting the tach signal normally and then the pump is stopped so the pump signal goes constantly high, which may indicate a stalled pump impeller, failed pump motor, or pump has been disconnected. If the coolant temperature is outside the safe range, the signal will be constantly low. For example, plot (D) of FIG. 5 shows a scenario where pump 20 is operating normally and pump signal is reporting the tach signal normally and then the pump signal goes constantly low, which may indicate an out-of-bounds high temperature. System 10 may be configured such that this constantly low pump signal 22 will have priority over normal pump speed signals. If pump 20 has an internal failure, or for other reason stops, pump signal 22 will be set constantly high. The constantly high condition representing an internal failure may have priority over the pump speed signal and the out-of-bounds coolant temperature signal (i.e., constantly low).

According to some embodiments, pump signal 22 may report the tach signal for the pump normally via 4 pulses per rotation while the frequency of this signal represents the speed of the pump, and the duty cycle of the signal represent the coolant temperature. If pump 20 is stopped, the frequency will be set to a low value, and the duty cycle may continue representing the coolant temperature. If pump 20 has an internal failure, the signal may be set constantly high. The constantly high condition representing an internal failure may have priority over the other signals.

FIG. 5 is a schematic of a liquid cooling system 100. System 100 may include all or a portion of the components as system 10. System 100 may also include a coolant measuring device 34 operatively connected to the temperature sensor 25 and in fluid communication with cold plate 16 and the flow path of the coolant. Coolant measuring device 34, may be for example, a flow sensor configured to measure the flow rate of coolant through system 100 or a pressure sensor configured to measure the pressure of coolant within system 100. In some embodiments, device 34 may be integrated as part of cold plate 16 or assembly 30, for example, mounted to the PCBA. In other embodiments, device 34 may be positioned elsewhere separate from cold plate 16 along the flow path of the coolant within system 100. For example, device 34 may be mounted in-line with the conduit between cold plate 16 and cooling device 18.

Device 34 may be configured to receive the coolant temperature signal and send a device signal 36 to control system 24 associated with computer 12 or heat generating electronic device 14. As described herein, most current computers have a tachometer (tach) signal port available that is intended to be used to monitor the speed of a pump or fan and also detect irregular operation of the pump or fan. System 100 as described herein, may be configured to utilize the existing tach signal port of control system 24 of computer 12 to receive device signal 36, which may provide information about device 34 as well as the coolant temperature. Device signal 36 may function similar to pump signal 22 described herein, such that device signal 36 may be programmed to include information about device 34 as well as the coolant temperature. For example, device signal 36 may represent a measurement signal (e.g., pressure or flow) for device 34 and the coolant temperature signal of the coolant measured by temperature sensor 26. In some embodiments, out-of-bound conditions measured by device 34 (e.g., pressure or flow) may also be determined and the device signal 36 may be used to indicate the out-of-bound condition to a control system by holding the signal high or low. In some embodiments, the measured pressure and/or flow may be utilized to estimate the temperature of the coolant enabling temperature measurement without a temperature sensor.

In some embodiments, device 34 may be programmed to send a device signal 36 representative of a running pump to control system 24. Device 34 may be programmed to send the device signal 36, whether or not the signal is representative of an actual pump, while the coolant temperature is in-bounds and when the coolant temperature goes out-of-bounds the device signal 36 is held at a specific state indicating an out-of-bounds temperature to control system 24.

Other embodiments of the present disclosure will be apparent to those skilled in the art from consideration of the specification and practice of the present disclosure disclosed herein. It is intended that the specification and examples be exemplary only, with a true scope and spirit of the present disclosure being indicated by the following claims.

What is claimed is:

1. A liquid cooling system for a heat generating electronic device, comprising:
a cold plate configured to be positioned on the heat generating electronic device, the cold plate configured to pass a coolant therethrough;
a temperature sensor configured to generate a coolant temperature signal indicative of a temperature of the coolant; and
a pump in fluid communication with the cold plate, the pump configured to circulate the coolant through the cold plate and send a pump signal to a control system associated with the heat generating electronic device;
wherein the pump signal represents a tachometer signal for the pump and the coolant temperature signal of the coolant.

2. The liquid cooling system of claim 1, comprising a plurality of cold plates positioned on a plurality of heat generating electronic devices, the cold plates are configured to pass a coolant therethrough.

3. The liquid cooling system of claim 2, comprising a plurality of pumps in fluid communication with the plurality of cold plates, the plurality of pumps are configured to circulate the coolant through the plurality of cold plates.

4. The liquid cooling system of claim 1, wherein the tachometer signal and the coolant temperature signal are time sliced to form the pump signal.

5. The liquid cooling system of claim 4, wherein the pump signal alternatives between a speed-reporting window that represents the tachometer signal and a coolant temperature reporting window that represents the coolant temperature signal on a fixed time basis.

6. The liquid cooling system of claim 5, wherein the pump signal will include between 45 and 600 pulses per second during the speed-reporting window, the number of pulses representing a number of rotations per minute for the pump.

7. The liquid cooling system of claim 5, wherein the pump signal will include between 1000 and 1150 pulses per second during the coolant temperature reporting window, the number of pulses representing the temperature in Celsius plus 1000.

8. The liquid cooling system of claim 4, wherein the pump signal is sent to the control system via binary encoding according to a serial communication protocol where the tachometer signal is represented by a two-byte value and the coolant temperature signal is represented by a one-byte value.

9. The liquid cooling system of claim 1, wherein a frequency of the pump signal represents the tachometer signal and the duty cycle of the pump signal represents the coolant temperature signal.

10. The liquid cooling system of claim 1, further comprising an ambient temperature sensor configured to measure the ambient temperature around the pump, wherein the ambient temperature is used to determine an offset that is applied to the temperature of the coolant.

11. The liquid cooling system of claim 1, wherein the control system uses the coolant temperature signal to identify when the coolant temperature is out-of-bounds and determines corrective action based on how far the coolant temperature is out-of-bounds.

12. The liquid cooling system of claim 11, wherein the correction action includes forcing the pump to run at full speed.

13. A method of controlling a liquid cooling system for a heat generating electronic device, comprising:
circulating a coolant through a cold plate configured to be positioned on the heat generating electronic device;
measuring a temperature of the coolant via a temperature sensor configured to generate a coolant temperature signal indicative of the temperature of the coolant; and
pumping the coolant through the cold plate via a pump configured to send a pump signal to a control system associated with the heat generating electronic device;
wherein the pump signal represents a tachometer signal for the pump and the coolant temperature signal of the coolant.

14. The method of claim 13, furthering comprising time slicing the tachometer signal and the coolant temperature signal to form the pump signal.

15. The method of claim 14, wherein time slicing includes alternating the pump signal between a speed reporting window that represents the tachometer signal and a coolant temperature reporting window that represents the coolant temperature signal on a fixed time basis.

16. The method of claim 15, wherein the pump signal includes between 45 and 600 pulses per second during the speed-reporting window, the number of pulses representing a number of rotations per minute for the pump.

17. The method of claim 15, wherein the pump signal includes between 1000 and 1150 pulses per second during the coolant temperature reporting window, the number of pulses representing the temperature in Celsius plus 1000.

18. The method of claim 14, wherein the pump signal is sent to the control system via binary encoding according to a serial communication protocol where the tachometer signal is represented by a two-byte value and the coolant temperature is represented by a one-byte value.

19. The method of claim 13, wherein a frequency of the pump signal represents the tachometer signal and the duty cycle of the pump signal represents the coolant temperature signal.

20. The method of claim 13, further comprising identifying when the coolant temperature is out-of-bounds and determining corrective action based on how far the coolant temperature is out-of-bounds.

21. The method of claim 13, further comprising measuring an ambient air temperature around the pump and using the ambient air temperature to determine an offset that is applied to the temperature of the coolant.

22. A liquid cooling system for a heat generating electronic device, comprising:
a cold plate configured to be positioned on the heat generating electronic device, the cold plate configured to pass a coolant therethrough;
a temperature sensor configured to generate a coolant temperature signal indicative of a temperature of the coolant; and
a pump in fluid communication with the cold plate, the pump configured to circulate the coolant through the cold plate and send a pump signal to a control system associated with the heat generating electronic device;
wherein the pump signal represents a tachometer signal for the pump and when the coolant temperature goes out-of-bounds the pump signal is held at a specific state indicating an out-of-bounds temperature to the control system.

23. The liquid cooling system according to claim 22, wherein the pump signal is held high or low when the coolant temperature goes out of bounds and the pump signal is held high if the pump experiences a failure.

24. The liquid cooling system according to claim 23, where a failure of the pump includes at least one of a stalled pump, power loss, and disconnected cable.
